(19) United States
(12) Patent Application Publication
(10) Pub. No.: US 2024/0192275 A1
(43) Pub. Date: Jun. 13, 2024

(54) COMPUTING TERMINAL FOR PARAMETER IDENTIFICATION

(71) Applicant: Shanghai Makesens Energy Storage Technology Co., Ltd., Shanghai (CN)

(72) Inventors: Jian ZHAO, Shanghai (CN); Pei SONG, Shanghai (CN); Guopeng ZHOU, Shanghai (CN); Zonglin CAI, Shanghai (CN); Yunkai WU, Shanghai (CN); Yan MA, Shanghai (CN); Xiao YAN, Shanghai (CN); Enhai ZHAO, Shanghai (CN)

(73) Assignee: Shanghai Makesens Energy Storage Technology Co., Ltd., Shanghai (CN)

(21) Appl. No.: 18/531,723

(22) Filed: Dec. 7, 2023

(30) Foreign Application Priority Data
Dec. 9, 2022 (CN) 202211582360.8

(51) Int. Cl. G01R 31/367

(52) U.S. Cl. CPC G01R 31/367

(57) ABSTRACT

A computing terminal for parameter identification is provided. The computing terminal includes an FPGA which includes a solid-phase calculating module, a liquid-phase calculating module, and an electrolytic coupling calculating module. At least some of the solid-phase calculating module, the liquid-phase calculating module, and the electrolytic coupling calculating module operate in parallel. Each of the calculating modules is configured to solve a corresponding differential equation to determine a corresponding electrochemical parameter of an electrochemical model. With the computing terminal for parameter identification, the FPGA has a low cost and parallel calculations are achieved at a hardware level, thereby speeding up processing, and improving processing efficiency.

### CROSS-REFERENCE TO RELATED APPLICATION

This application claims priority to Chinese Patent Application No. 202211582360.8, filed on Dec. 9, 2022, which is incorporated herein by its reference in its entirety.

### FIELD

The present disclosure relates to the technical field of electrochemical models, and in particular to a computing terminal for parameter identification.

### BACKGROUND

The increasingly widespread application of batteries leads to various economic losses caused by battery failures. Currently, a parameter (e.g., state of charge, or an effective voltage) of a battery is calculated mainly based on an equivalent circuit, an electrochemical model, and the like. In the equivalent circuit, the battery is equivalent to a circuit formed by a resistor and a capacitor, for calculating and evaluating the parameter of the battery. A P2D (pseudo-two-dimensional) model is an electrochemical model that simplifies various components of the battery into multiple small units, in order to simplify a calculating model, and then the parameter of the battery is calculated by using a differential equation.

Parameter identification is necessary in both the equivalent circuit and the electrochemical model. For example, the parameter identification for the electrochemical model is to determine an electrochemical parameter of the electrochemical model. The electrochemical model, having higher accuracy than the equivalent circuit, involves a large number of parameters and the complex differential equation, and thus has low efficiency in terms of the parameter identification. Although the efficiency may be improved by using a high-performance processor, the cost is high accordingly.

### SUMMARY

In order to solve the above problems, a computing terminal for parameter identification is provided according to embodiments of the present disclosure.

A computing terminal for parameter identification is provided according to embodiments of the present disclosure. The computing terminal includes an FPGA. The FPGA includes a solid-phase calculating module, liquid-phase calculating module, and an electrolytic coupling calculating module. At least some of the solid-phase calculating module, the liquid-phase calculating module, and the electrolytic coupling calculating module operate in parallel.

The solid-phase calculating module is configured to solve a solid-phase differential equation to determine a solid-phase electrochemical parameter of an electrochemical model.

The liquid-phase calculating module is configured to solve a liquid-phase differential equation to determine a liquid-phase electrochemical parameter of the electrochemical model.

The electrolytic coupling calculating module is configured to solve an electrolytic coupling differential equation to determine an electrolytic coupling electrochemical parameter of the electrochemical model.

In an embodiment, a calculating module includes multiple calculating units, and the calculating module is the solid-phase calculating module, the liquid-phase calculating module, or the electrolytic coupling calculating module.

Some of the multiple calculating units are configured to recursively optimize a coefficient matrix of an original linear equation system, where the original linear equation system is obtained by discretizing a to-be-solved differential equation.

The other calculating units are configured to recursively solve a linear equation system obtained by optimizing the coefficient matrix.

In an embodiment, the calculating module includes: a first calculating unit, a second calculating unit, a third calculating unit, and a fourth calculating unit.

The first calculating unit is configured to recursively calculate elements in a lower triangular matrix determined by performing LU decomposition on the coefficient matrix of the original linear equation system.

The second calculating unit is configured to recursively calculate elements in an upper triangular matrix determined by performing the LU decomposition on the coefficient matrix of the original linear equation system.

The third calculating unit is configured to recursively solve a first linear equation system to determine an unknown matrix of the first linear equation system, where a coefficient matrix of the first linear equation system is the lower triangular matrix, and a constant matrix of the first linear equation system is a constant matrix of the original linear equation system.

The fourth calculating unit is configured to recursively solve a second linear equation system to determine an unknown matrix of the second linear equation system, where a coefficient matrix of the second linear equation system is the upper triangular matrix, and a constant matrix of the second linear equation system is the unknown matrix of the first linear equation system.

In an embodiment, the coefficient matrix of the original linear equation system is a tridiagonal matrix.

In an embodiment, the first calculating unit is configured to calculate an element 1ᵢ at an i-th row and an (i−1)-th column in the lower triangular matrix after the second calculating unit determines an element uᵢ₋₁ at an (i−1)-th row and an (i−1)-th column in the upper triangular matrix.

The second calculating unit is configured to calculate an element uᵢ at an i-th row and an i-th column in the upper triangular matrix after the first calculating unit determines the element 1ᵢ at the i-th row and the (i−1)-th column in the lower triangular matrix.

The third calculating unit is configured to calculate an i-th element yᵢ in the unknown matrix of the first linear equation system after the first calculating unit determines the element 1ᵢ at the i-th row and the (i−1)-th column in the lower triangular matrix.

The fourth calculating unit is configured to calculate the unknown matrix of the second linear equation system after the third calculating unit determines the unknown matrix of the first linear equation system.

In an embodiment, the second calculating unit is configured to calculate the element uᵢ at the i-th row and the i-th column in the upper triangular matrix and the third calculating unit is configured to calculate the i-th element yᵢ in the unknown matrix of the first linear equation system in a calculation period after the element 1ᵢ at the i-th row and the (i−1)-th column in the lower triangular matrix is determined by the first calculating unit.

The first calculating unit is configured to calculate an element 1ᵢ₊₁ at an (i+1)-th row and the i-th column in the lower triangular matrix in a calculation period after the element uᵢ at the i-th row and the i-th column in the upper triangular matrix is determined by the second calculating unit.

In an embodiment, the fourth calculating unit is configured to calculate a k-th element xₖ in the unknown matrix of the second linear equation system based on recursion in reverse order, where k=n−1, n−2, . . . , 1, and n represents the number of nodes for discretizing the differential equation.

In an embodiment, the element 1ᵢ at the i-th row and the (i−1)-th column in the lower triangular matrix is calculated from

lᵢ=aᵢ/uᵢ₋₁.

The element uᵢ at the i-th row and the i-th column in the upper triangular matrix is calculated from

$$\{ \begin{matrix}{u}_{1} = {b}_{1} \\ {u}_{i} = {b}_{i} - {c}_{i - 1} {l}_{i}\end{matrix} .$$

The i-th element yᵢ in the unknown matrix of the first linear equation system is calculated from

$$\{ \begin{matrix}{y}_{1} = {d}_{1} \\ {y}_{i} = {d}_{i} - {l}_{i} {y}_{i - 1}\end{matrix} .$$

A k-th element xx in the unknown matrix of the second linear equation system is calculated from

$$\{ \begin{matrix}{x}_{n} = {y}_{n} / {u}_{n} \\ {x}_{k} = ( {y}_{k} - {c}_{k} {x}_{k + 1} ) / {u}_{k}\end{matrix} .$$

where i=2, 3, . . . , n, k=n−1, n−2, . . . , 1, n represents the number of nodes for discretizing the differential equation; aᵢ represents an element at an i-th row and an (i−1)-th column in the tridiagonal matrix, bᵢ represents an element at the i-th row and an i-th column in the tridiagonal matrix, cᵢ represents an element at the i-th row and an (i+1)-th column in the tridiagonal matrix, and dᵢ represents an i-th element in the constant matrix of the original linear equation system; b₁ represents an element at a first row and a first column in the tridiagonal matrix, c₁ represents an element at the first row and a second column in the tridiagonal matrix, d₁ represents a first element in the constant matrix of the original linear equation system, uᵢ represents an element at a first row and a first column in the upper triangular matrix, and y₁ represents a first element in the unknown matrix of the first linear equation system; and xₙ represents an n-th element in the unknown matrix of the second linear equation system.

In an embodiment, the solid-phase calculating module includes a positive solid-phase calculating module for determining a positive solid-phase electrochemical parameter and a negative solid-phase calculating module for determining a negative solid-phase electrochemical parameter.

The liquid-phase calculating module includes a positive liquid-phase calculating module for determining a positive liquid-phase electrochemical parameter and a negative liquid-phase calculating module for determining a negative liquid-phase electrochemical parameter.

The electrolytic coupling calculating module includes a positive electrolytic coupling calculating module for determining a positive electrolytic coupling electrochemical parameter and a negative electrolytic coupling calculating module for determining a negative electrolytic coupling electrochemical parameter.

In an embodiment, the computing terminal further includes a processing system.

The FPGA is configured to transmit the determined electrochemical parameters to the processing system.

In the solutions according to the embodiments of the present disclosure, multiple calculating modules for solving different differential equations of the electrochemical model are implemented by the FPGA, to determine multiple electrochemical parameters of the electrochemical model, so that the parameter identification is performed by hardware. The FPGA has a low cost. Further, some calculating modules can operate in parallel, that is, parallel calculations can be implemented by hardware, thereby speeding up processing, and improving processing efficiency. The calculating module includes multiple calculating units. Some of the calculating units are configured to simplify the coefficient matrix of the original linear equation system, and the other calculating units are configured to solve the simplified linear equation system, thereby speeding up the solving. Moreover, the calculating units perform calculation recursively, that is, one calculating unit starts the calculation immediately after another calculating unit acquires a partial calculation result, thereby achieving parallel processing and further improving the processing efficiency.

Preferred embodiments are described below in detail with reference to the drawings so that the above objects, features and advantages of the present disclosure are readily understandable.

### BRIEF DESCRIPTION OF THE DRAWINGS

In order to more clearly illustrate technical solutions in embodiments of the present disclosure or in the conventional technology, the drawings to be used in the description of the embodiments or the conventional technology are briefly described below. It is apparent that the drawings in the following description show only some embodiments of the present disclosure, and other drawings may be obtained by those skilled in the art from the drawings without any creative work.

FIG. 1 is a schematic structural diagram illustrating a computing terminal according to an embodiment of the present disclosure;

FIG. 2 is a schematic structural diagram illustrating the computing terminal according to another embodiment of the present disclosure;

FIG. 3 is a timing diagram for four calculating units during operation according to an embodiment of the present disclosure;

FIG. 4 is a schematic structural diagram illustrating an FPGA according to an embodiment of the present disclosure; and

FIG. 5 is a schematic structural diagram illustrating the computing terminal according to another embodiment of the present disclosure.

### DETAILED DESCRIPTION OF THE EMBODIMENTS

In the description of the present disclosure, it should be understood that the orientation or positional relationships indicated by terms such as “center”, “longitudinal”, “lateral”, “length”, “width”, “thickness”, “up”, “down”, “forward”, “backward”, “left”, “right”, “vertical”, “horizontal”, “top”, “bottom”, “inner”, “outer”, “clockwise”, “anticlockwise” and the like are based on the orientation or positional relationships shown in the drawings, and are merely for the convenience of describing the present disclosure and the simplification of the description instead of indicating or implying that the device or component referred must be arranged in a particular orientation, or be constructed and operated in a particular orientation, and therefore should not be construed as a limitation to the scope of the present disclosure.

Furthermore, the terms “first” and “second” are merely for purpose of description, and should not be construed as indicating or implying relative importance or implying the number of the indicated technical features. Therefore, the feature defined by “first” and “second” may explicitly or implicitly be one or more in number. In the description of the present disclosure, “multiple” indicates two or more, unless specifically defined otherwise.

In the present disclosure, unless otherwise clearly specified and limited, the terms “installation”, “linkage”, “connection”, “fixation” and the like should be interpreted in a broad sense. For example, the connection may be a fixed connection, a detachable connection, an integral connection, a mechanical connection, an electrical connection, a direct connection, an indirect connection through an intermediate medium, or an internal communication between two components. Those skilled in the art can understand specific meaning of such terms herein based on context.

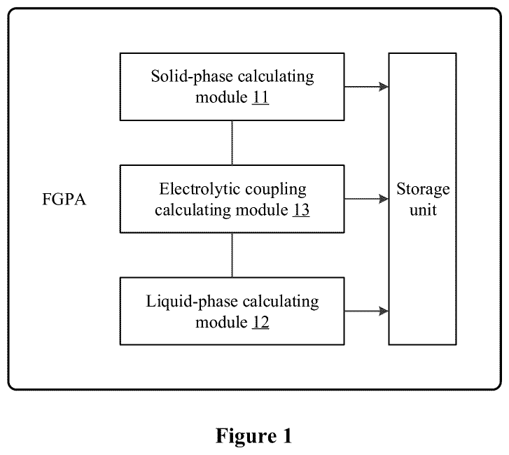

According to the conventional technology, parameter identification for an electrochemical model is performed by software programming. According to the embodiments of the present disclosure, an electrochemical model algorithm is deployed in an FPGA (Field Programmable Gate Array) based on features of hardware acceleration, so as to speed up the parameter identification. Specifically, a computing terminal for parameter identification is provided according to an embodiment of the present disclosure. As shown in FIG. 1, the computing terminal includes an FPGA. Further, the FPGA includes a calculating module for solving a differential equation. As shown in FIG. 1, the FPGA includes a solid-phase calculating module 11, a liquid-phase calculating module 12, and an electrolytic coupling calculating module 13. At least some of the solid-phase calculating module 11, the liquid-phase calculating module 12, and the electrolytic coupling calculating module 13 operate in parallel, that is, at least part of the calculating modules separately operate to achieve parallel calculations.

The solid-phase calculating module 11 is configured to solve a solid-phase differential equation to determine a solid-phase electrochemical parameter of the electrochemical model. The liquid-phase calculating module 12 is configured to solve a liquid-phase differential equation to determine a liquid-phase electrochemical parameter of the electrochemical model. The electrolytic coupling calculating module 13 is configured to solve an electrolytic coupling differential equation to determine an electrolytic coupling electrochemical parameter of the electrochemical model.

In the embodiment of the present disclosure, the computing terminal includes the FPGA, which is a programmable device. A programmable logic unit in the FPGA is flexibly configured to implement various logic functions. The FPGA in the embodiment of the present disclosure includes multiple modules with different logical functions, namely, the calculating modules. Each of the calculating modules is configured to solve a corresponding differential equation.

The electrochemical model involves many electrochemical parameters (such as a solid-phase diffusion coefficient, a liquid-phase diffusion coefficient, a lithium ion concentration, and a diaphragm area) and multiple differential equations. For example, the differential equations include a differential equation established based on Fick's second law for the solid-phase diffusion coefficient and a lithium ion concentration gradient, an equation established through a solid-phase surface concentration and a lithium ion exchange flux for solving a liquid-phase charge balance, and a Bulter-Volmer equation for an interface between an electrolyte and an electrode. The differential equations are commonly used in the electrochemical model, which are not described in detail in this embodiment. In the embodiments of the present disclosure, a differential equation related to the solid-phase electrochemical parameter (e.g., a solid-phase lithium ion concentration) is referred to as the “solid-phase differential equation”. A calculating module for solving the solid-phase differential equation is referred to as the solid-phase calculating module. A differential equation related to the liquid-phase electrochemical parameter (e.g., the liquid-phase lithium ion concentration) is referred to as the “liquid-phase differential equation”. A calculating module for solving the liquid-phase differential equation is referred to as the liquid-phase calculating module. A differential equation related to electrolytic coupling electrochemical parameter (e.g., an exchange flux at the interface between the electrolyte and the electrode) is referred to as the “electrolytic coupling differential equation”. A calculating module for solving the electrolytic coupling differential equation is referred to as the electrolytic coupling calculating module.

In the embodiment of the present disclosure, at least some of the differential equations processed by the calculating modules in the FPGA are uncoupled, that is, these differential equations are solved separately, and thus operate in parallel. For example, the solid-phase calculating module 11 and the liquid-phase calculating module 12 may operate in parallel, that is, solve corresponding differential equations simultaneously to determine corresponding electrochemical parameters. The electrolytic coupling calculating module 13 operates to solve the electrolytic coupling differential equation, so as to calculate some parameters of the battery, such as a terminal voltage of a lithium battery (i.e. a potential difference between a positive electrode and a negative electrode in the solid phase). Moreover, as shown in FIG. 1, the FPGA may further include a storage unit. The storage unit is configured to store the electrochemical parameter calculated by each of the calculating modules.

In the computing terminal for parameter identification according to the embodiment of the present disclosure, multiple calculating modules for solving different differential equations of the electrochemical model are implemented by the FPGA, to determine multiple electrochemical parameters of the electrochemical model, so that the parameter identification is performed by hardware. The FPGA has a low cost. Further, some calculating modules can operate in parallel, that is, parallel calculations can be implemented by hardware, thereby speeding up processing, and improving processing efficiency.

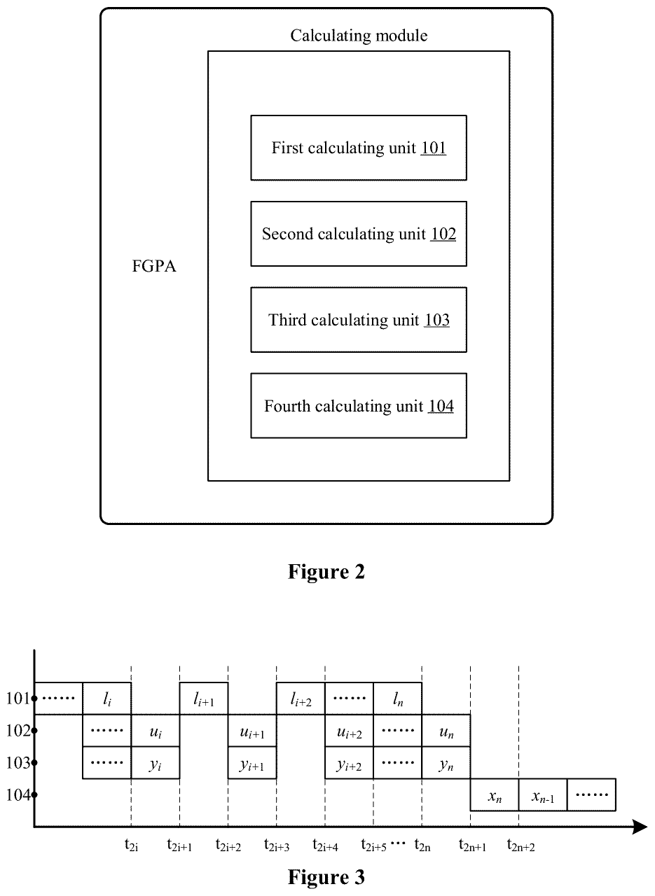

In an embodiment, as described above, the FPGA includes a calculating module. For example, the calculating module may be the solid-phase calculating module 11, the liquid-phase calculating module 12, or the electrolytic coupling calculating module 13. In the embodiment of the present disclosure, the calculating module includes multiple calculating units. As shown in FIG. 2, the calculating module includes four calculating units. For the convenience of description, these four calculating units are referred to as a first calculating unit 101, a second calculating unit 102, a third calculating unit 103, and a fourth calculating unit 104. Some of the calculating units are configured to recursively optimize a coefficient matrix of an original linear equation system. The original linear equation system is obtained by discretizing a to-be-solved differential equation. The other calculating units are configured to recursively solve a linear equation system obtained by optimizing the coefficient matrix.

In the embodiment of the present disclosure, the calculating modules corresponds to to-be-solved differential equations. For example, the to-be-solved differential equation corresponding to the solid-phase calculating module 11 is the solid-phase differential equation. In the embodiment of the present disclosure, a differential equation is discretized to so as to be transformed into a linear equation system. Therefore, the differential equation is solved by solving the linear equation system is solved. Moreover, the linear equation system may be represented in a matrix. Specifically, the differential equation is transformed into the linear equation system in form of matrix, and the linear equation system may be expressed by the following equation (1).

AX=D (1)

X represents an unknown matrix of the linear equation system and is an n-dimensional column vector including n unknown quantities. A represents a coefficient matrix of the linear equation system and is an n×n matrix. D represents a constant matrix of the linear equation system and is a column vector including n known quantities, that is, an n-dimensional column vector.

In the embodiment of the present disclosure, in order to discretize the differential equation of the electrochemical model, the number n of nodes is first determined, and then the differential equation is transformed into a linear equation system including n equations. For example, the differential equation may be transformed into the linear equation system based on a finite difference method. For example, a positive electrode of the battery is discretized into n nodes along an x-axis (from the positive electrode to a negative electrode of the battery), a parameter at each of the nodes may be determined through collection and other methods, so as to determine elements in the coefficient matrix A and elements in the constant matrix D, that is, the coefficient matrix A and the constant matrix D are known.

For example, in order to calculate the solid-phase lithium ions concentration, the solid-phase calculating module 11 constructs the coefficient matrix A. The coefficient matrix A is a unit stiffness matrix physically indicates influence parameters at different nodes for the purpose that displacements of lithium ions at other nodes remains at 0 when a lithium ion at a node is displaced by a unit in a coordinate axis direction in the solid phase. The elements in the coefficient matrix A may be determined by collecting the parameters at corresponding nodes. The constant matrix represents a concentration change matrix of electrolytic coupling lithium ions. The unknown matrix X is the to-be-solved matrix of the solid-phase lithium ion concentration.

In the embodiment of the present disclosure, for the convenience of description, a linear equation system directly transformed from the differential equation is referred to as the original linear equation system. A coefficient matrix of the original linear equation system is the above matrix A, and a constant matrix of the original linear equation system is the above matrix D. Some of the calculating units of the calculating module optimize the coefficient matrix (e.g., the matrix A) of the original linear equation system, to simplify the coefficient matrix. The other calculating units solve the linear equation system having the optimized coefficient matrix (instead of the original linear equation system), which can rapidly obtain the solution result. Moreover, the calculating units recursively optimize the coefficient matrix. That is, during the process of determining the optimized coefficient matrix, one or some elements in the optimized coefficient matrix are first determined, other elements in the optimized coefficient matrix are determined, and then other unknown elements in the optimized coefficient matrix are determined, until all elements in the optimized coefficient matrix are determined. Similarly, the other calculating units recursively solve the unknown matrix, to sequentially calculate the unknown quantities in the unknown matrix.

In the embodiment of the present disclosure, the calculating module includes multiple calculating units. Some of the calculating units are configured to simplify the coefficient matrix of the original linear equation system, and the other calculating units are configured to solve the simplified linear equation system, which can speed up the solving. Moreover, the calculating units perform calculation recursively, that is, one calculating unit starts the calculation immediately after another calculating unit acquires a partial calculation result, thereby achieving parallel processing and further improving the processing efficiency. In addition, those skilled in the art can understand that the calculating modules in the embodiment of the present disclosure solve the discretized original linear equation system without focusing on the process of discretizing the differential equation into the original linear equation system.

In an embodiment, the coefficient matrix of the original linear equation system is optimized through LU decomposition. Specifically, as shown in FIG. 2, the calculating module includes a first calculating unit 101, a second calculating unit 102, a third calculating unit 103, and a fourth calculating unit 104.

The first calculating unit 101 is configured to recursively calculate elements in a lower triangular matrix determined by performing LU decomposition on the coefficient matrix of the original linear equation system. The second calculating unit 102 is configured to recursively calculate elements in an upper triangular matrix determined by performing LU decomposition on the coefficient matrix of the original linear equation system. The third calculating unit 103 is configured to recursively solve a first linear equation system to determine an unknown matrix of the first linear equation system. A coefficient matrix of the first linear equation system is the lower triangular matrix, and a constant matrix of the first linear equation system is the constant matrix of the original linear equation system. The fourth calculating unit 104 is configured to recursively solve a second linear equation system to determine an unknown matrix of the second linear equation system. A coefficient matrix of the second linear equation system is the upper triangular matrix, and a constant matrix of the second linear equation system is the unknown matrix of the first linear equation system.

In the embodiment of the present disclosure, the LU decomposition is performed on the coefficient matrix of the original linear equation system to obtain the lower triangular matrix L and the upper triangular matrix U. The LU decomposition is existing technology, and thus is not described in detail herein. In the embodiment of the present disclosure, in a case that the original linear equation system satisfies the above equation (1), that is, the coefficient matrix of the original linear equation system is the matrix A, the unknown matrix of the original linear equation system is the matrix X, and the constant matrix of the original linear equation system is the matrix D, the LU decomposition is performed on the coefficient matrix A, that is, A=L×U. Correspondingly, the above equation (1) may be transformed into the following equation (2).

LUX=D (2)

L represents the lower triangular matrix, U represents the upper triangular matrix, X represents the unknown matrix of the original linear equation system, and D represents the constant matrix of the original linear equation system. Since each of elements in the coefficient matrix A may be determined through collection or calculation, the lower triangular matrix L and the upper triangular matrix U are also known.

In a case that the number of equations in the original linear equation system is n, that is, the number of nodes is n when the differential equation is discretized, the lower triangular matrix L and the upper triangular matrix U each are an n×n matrix. The unknown matrix X and the constant matrix D of the original linear equation system each are an n× 1 matrix, that is, an n-dimensional column vector. Moreover, a calculation result of UX is also an n-dimensional column vector. In the embodiment of the present disclosure, a matrix Y represents UX, that is, Y=UX. Therefore, the above equation (2) may be transformed into the following equation (3).

LY=D (3)

Since each of the elements in the coefficient matrix A and each of the elements in the constant matrix D of the original linear equation system are determined through collection or calculation and the lower triangular matrix L and the upper triangular matrix U obtained through the LU decomposition are known, each of elements in the matrix Y can be obtained by solving the above equation (3). For the convenience of description, in the embodiment of the present disclosure, the linear equation system represented by the equation (3) is referred to as the first linear equation system. From the equation (3), it can be seen that the coefficient matrix of the first linear equation system is the lower triangular matrix L, the constant matrix of the first linear equation system is the constant matrix D of the original linear equation system, and the unknown matrix of the first linear equation system is the matrix Y.

In addition, as described above, the unknown matrix X of the original linear equation system satisfies the following equation (4).

UX=Y (4)

After the first linear equation system is solved, that is, after the equation (3) is solved, the unknown matrix Y of the first linear equation system is determined. Further, the upper triangular matrix U is also known. Therefore, the equation (4) is solved to obtain the matrix X, that is, the unknown matrix X of the original linear equation system. For the convenience of description, in the embodiment of the present disclosure, the linear equation system represented by the equation (4) is referred to as the second linear equation system. From the equation (4), it can be seen that the coefficient matrix of the second linear equation system is the upper triangular matrix U, the constant matrix of the second linear equation system is the unknown matrix Y of the first linear equation system, and the unknown matrix of the second linear equation system is the matrix X that is also the unknown matrix of the original linear equation system.

In the embodiment of the present disclosure, the calculating module includes four calculating units, namely, the first calculating unit 101, the second calculating unit 102, the third calculating unit 103, and the fourth calculating unit 104. The first calculating unit 101 is configured to determine the lower triangular matrix L. The second calculating unit 102 is configured to determine the upper triangular matrix U. The third calculating unit 103 is configured to solve the first linear equation system. The fourth calculating unit 104 is configured to solve the second linear equation system.

Specifically, during the LU decomposition, elements in the lower triangular matrix L and elements in the upper triangular matrix U are recursively determined. For example, the first calculating unit 101 determines the elements in the lower triangular matrix L column by column, and the second calculating unit 102 determines the elements in the upper triangular matrix U row by row. Moreover, the first calculating unit 101 and the second calculating unit 102 may perform the calculation in parallel, so that the lower triangular matrix L and the upper triangular matrix U can be rapidly determined. For example, the first calculating unit 101 may determine an element at a third row and a first column of the lower triangular matrix L after determining an element at a second row and the first column of the lower triangular matrix L. At the same time, the second calculating unit 102 may determine an element at a second row and a second column of the upper triangular matrix U.

All diagonal elements in the upper triangular matrix L are 1, that is, an element at an i-th row and an i-th column in the upper triangular matrix L is 1. Therefore, the third calculating unit 103 may, when solving the first linear equation system, recursively determine the elements in the unknown matrix Y of the first linear equation system, that is, determine elements y₁, y₂, . . . , yᵢ, . . . , yₙ in the unknown matrix Y sequentially. Moreover, when elements in the i-th row of the upper triangular matrix L are all known, the third calculating unit 103 may determine an i-th element yᵢ in the unknown matrix Y of the first linear equation system. Therefore, the third calculating unit 103 can also perform the calculation in parallel with the first calculating unit 101 and the second calculating unit 102, to determine the elements in the unknown matrix Y of the first linear equation system, thereby further improving the solving efficiency.

Similarly, the fourth calculating unit 104 may recursively solve the second linear equation system, so as to determine the unknown matrix X of the second linear equation system. The unknown matrix X is a solution of the differential equation, so as to determine the corresponding electrochemical parameter, thereby achieving the parameter identification.

In an embodiment, after the differential equation is discretized into the original linear equation system, the coefficient matrix A of the original linear equation system is a tridiagonal matrix, that is, only elements on a main diagonal, a low diagonal, and a high diagonal in the coefficient matrix A are not 0, and the other elements are all 0. The differential equation may be transformed into the linear equation system with the coefficient matrix that is the tridiagonal matrix based on the finite difference method, which is not described in detail in this embodiment. In the embodiment of the present disclosure, the coefficient matrix A of the original linear equation system is an n×n matrix. The equation (1) may be expressed as the following equation (5).

$$AX = [ \begin{matrix}{b}_{1} & {c}_{1} & & & & & \\ {a}_{2} & {b}_{2} & {c}_{2} & & & & \\ & ⋱ & ⋱ & ⋱ & & & \\ & & {a}_{i} & {b}_{i} & {c}_{i} & & \\ & & & ⋱ & ⋱ & ⋱ & \\ & & & & {a}_{n - 1} & {b}_{n - 1} & {c}_{n - 1} \\ & & & & & {a}_{n} & {b}_{n}\end{matrix} ] [ \begin{matrix}{x}_{1} \\ {x}_{2} \\ ⋮ \\ {x}_{i} \\ ⋮ \\ {x}_{n - 1} \\ {x}_{n}\end{matrix} ] = [ \begin{matrix}{d}_{1} \\ {d}_{2} \\ ⋮ \\ {d}_{i} \\ ⋮ \\ {d}_{n - 1} \\ {d}_{n}\end{matrix} ] \qquad ( 5 )$$

aᵢ, bᵢ, and cᵢ represent the elements in the tridiagonal matrix A, where i=2, 3, . . . , n. From the above equation (5), it can be seen that aᵢ represents an element at an i-th row and an (i−1)-th column in the tridiagonal matrix A, and there is no element a₁ in the tridiagonal matrix A. b₁ represents an element at a first row and a first column in the tridiagonal matrix A, and bᵢ represents an element at the i-th row and an i-th column in the tridiagonal matrix A. c₁ represents an element at the first row and a second column in the tridiagonal matrix A, and cᵢ represents an element at the i-th row and an (i+1)-th column in the tridiagonal matrix A. Since there is no element at an n+1 column in the tridiagonal matrix A, no element cₙ exists. In other words, when i is equal to n, the element cₙ is meaningless and therefore is unnecessarily solved. Similarly, x₁ represents the first element in the unknown matrix X of the original linear equation system, and xᵢ represents an i-th element in the unknown matrix X of the original linear equation system. d₁ represents a first element in the constant matrix D of the original linear equation system, and dᵢ represents an i-th element in the constant matrix D of the original linear equation system.

The LU decomposition is performed on the tridiagonal matrix A to obtain the lower triangular matrix L and the upper triangular matrix U.

$$L = [ \begin{matrix}1 & & & & & & \\ {l}_{2} & 1 & & & & & \\ & ⋱ & ⋱ & & & & \\ & & {l}_{i} & 1 & & & \\ & & & ⋱ & ⋱ & & \\ & & & & {l}_{n - 1} & 1 & \\ & & & & & {l}_{n} & 1\end{matrix} ] U = [ \begin{matrix}{u}_{1} & {c}_{1} & & & & & \\ & {u}_{2} & {c}_{2} & & & & \\ & & ⋱ & ⋱ & & & \\ & & & {u}_{i} & {c}_{i} & & \\ & & & & ⋱ & ⋱ & \\ & & & & & {u}_{n - 1} & {c}_{n - 1} \\ & & & & & & {u}_{n}\end{matrix} ]$$

1ᵢ represents an element at an i-th row and an (i−1)-th column in the lower triangular matrix L. u₁ represents an element at a first row and a first column in the upper triangular matrix U. uᵢ represents an element at the i-th row and an i-th column in the upper triangular matrix U. i is equal to 2, 3, . . . , n. Similar to the tridiagonal matrix A expressed by the equation (5), elements in the lower triangular matrix L and the upper triangular matrix U not shown herein are all 0.

Moreover, the elements in the lower triangular matrix L and the elements in the upper triangular matrix U satisfy the following equation.

$$\{ \begin{matrix}{u}_{1} = {b}_{1} \\ {l}_{i} = {a}_{i} / {u}_{i - 1} \\ {u}_{i} = {b}_{i} - {c}_{i - 1} {l}_{i}\end{matrix} \qquad ( 6 )$$

where i=2, 3, . . . , n.

UX is expressed by an n-dimensional column vector Y=[y₁ y₂ . . . yᵢ . . . yₙ₋₁ yₙ]^{T}, and the above equation (3) may be transformed into the following equation (7).

$$LY = [ \begin{matrix}1 & & & & & & \\ {l}_{2} & 1 & & & & & \\ & ⋱ & ⋱ & & & & \\ & & {l}_{i} & 1 & & & \\ & & & ⋱ & ⋱ & & \\ & & & & {l}_{n - 1} & 1 & \\ & & & & & {l}_{n} & 1\end{matrix} ] [ \begin{matrix}{y}_{1} \\ {y}_{2} \\ ⋮ \\ {y}_{i} \\ ⋮ \\ {y}_{n - 1} \\ {y}_{n}\end{matrix} ] = [ \begin{matrix}{d}_{1} \\ {d}_{2} \\ ⋮ \\ {d}_{i} \\ ⋮ \\ {d}_{n - 1} \\ {d}_{n}\end{matrix} ] \qquad ( 7 )$$

where i=2, 3, . . . , n. The column vector Y is the unknown matrix of the first linear equation system. y₁ represents a first element in the unknown matrix Y of the first linear equation system. yᵢ represents an i-th element in the unknown matrix Y of the first linear equation system.

The first linear equation system is solved, that is, the equation (7) is solved to obtain the following equation (8).

$$\{ \begin{matrix}{y}_{1} = {d}_{1} \\ {y}_{i} = {d}_{i} - {l}_{i} {y}_{i - 1}\end{matrix} \qquad ( 8 )$$

Similarly, the above equation (4) may be transformed into the following equation (9).

$$UX = [ \begin{matrix}{u}_{1} & {c}_{1} & & & & & \\ & {u}_{2} & {c}_{2} & & & & \\ & & ⋱ & ⋱ & & & \\ & & & {u}_{i} & {c}_{i} & & \\ & & & & ⋱ & ⋱ & \\ & & & & & {u}_{n - 1} & {c}_{n - 1} \\ & & & & & & {u}_{n}\end{matrix} ] [ \begin{matrix}{x}_{1} \\ {x}_{2} \\ ⋮ \\ {x}_{i} \\ ⋮ \\ {x}_{n - 1} \\ {x}_{n}\end{matrix} ] = [ \begin{matrix}{y}_{1} \\ {y}_{2} \\ ⋮ \\ {y}_{i} \\ ⋮ \\ {y}_{n - 1} \\ {y}_{n}\end{matrix} ] \qquad ( 9 )$$

The second linear equation system is solved, that is, the equation (9) is solved to obtain the following equation.

$$\{ \begin{matrix}{x}_{n} = {y}_{n} / {u}_{n} \\ {x}_{k} = ( {y}_{k} - {c}_{k} {x}_{k + 1} ) / {u}_{k}\end{matrix} \qquad ( 10 )$$

where k=n−1, n−2, . . . , 1. xₙ represents an n-th element in the unknown matrix X of the original linear equation system, and xₖ represents a k-th element in the unknown matrix X of the original linear equation system. Those skilled in the art should understand that xx and xᵢ in the embodiment of the present disclosure may essentially represent the same meaning, and each of xₖ and xᵢ represents an element in the unknown matrix X of the original linear equation system.

In the embodiment of the present disclosure, the first calculating unit 101 is configured to determine an element 1ᵢ in the lower triangular matrix L. The second calculating unit 102 is configured to determine an element uᵢ in the upper triangular matrix U. From the above equation (6), it can be seen that after an element uᵢ₋₁ in the upper triangular matrix U is calculated, the first calculating unit 101 calculates the element 1ᵢ in the lower triangular matrix L from the equation of lᵢ=aᵢ/uᵢ₋₁. Similarly, after the element 1ᵢ in the lower triangular matrix L is calculated, the second calculating unit 102 calculates the element uᵢ in the upper triangular matrix U from the equation of uᵢ=bᵢ−cᵢ₋₁lᵢ. Specifically, the first calculating unit 101 is configured to calculate the element 1ᵢ at the i-th row and the (i−1)-th column in the lower triangular matrix L after the second calculating unit 102 determines the element uᵢ₋₁ at the (i−1)-th row and the (i−1)-th column in the upper triangular matrix U. An element u₁ at the first row and the first column in the upper triangular matrix U is the same as an element bᵢ at the first row and the first column in the tridiagonal matrix A, that is, u₁=b₁. Moreover, the second calculating unit 102 is configured to calculate the element uᵢ at the i-th row and the i-th column in the upper triangular matrix U after the first calculating unit 101 determines the element 1ᵢ at the i-th row and the (i−1)-th column in the lower triangular matrix L.

The third calculating unit 103 is configured to determine the elements in the unknown matrix Y of the first linear equation system. From the above equation (8), it can be seen that after the element 1ᵢ in the lower triangular matrix L is calculated, the third calculating unit 103 calculates the i-th element yᵢ in the unknown matrix of the first linear equation system from the equation of yᵢ=dᵢ—lᵢyᵢ₋₁. Specifically, the third calculating unit 103 is configured to calculate the i-th element yᵢ in the unknown matrix Y of the first linear equation system after the first calculating unit 101 determines the element 1ᵢ at the i-th row and the (i−1)-th column in the lower triangular matrix L.

The fourth calculating unit 104 is configured to determine elements in the unknown matrix X of the second linear equation system. From the above equation (10), it can be seen that after the elements in the unknown matrix Y of the first linear equation system are calculated, the fourth calculating unit 104 calculates the elements in the unknown matrix X of the second linear equation system. That is, the fourth calculating unit 104 is configured to calculate the unknown matrix of the second linear equation system after the third calculating unit 103 determines the unknown matrix of the first linear equation system. Moreover, from the above equation (10), it can be seen that the fourth calculating unit 104 is configured to calculate a k-th element xx in the unknown matrix X of the second linear equation system based on recursion in reverse order, and k=n−1, n−2, . . . , 1. That is, the fourth calculating unit 104 calculates xₙ, xₙ₋₁, xₙ₋₂, and so on in sequence until x₁ is calculated.

In the embodiment of the present disclosure, the first calculating unit 101 is configured to determine the lower triangular matrix L, the second calculating unit 102 is configured to determine the upper triangular matrix U, the third calculating unit 103 is configured to solve the first linear equation system, and the fourth calculating unit 104 is configured to solve the second linear equation system. The four calculating units perform different calculations recursively, thereby achieving rapid solution while simplifying the coefficient matrix A of the original linear equation system. Moreover, at least some calculating units can perform the calculation in parallel due to features of the matrix obtained by performing the LU decomposition. For example, the first calculating unit 101 determines the lower triangular matrix L while the second calculating unit 102 determines the upper triangular matrix U, thereby further improving the efficiency of solving the differential equation.

In an embodiment, in a calculation period after the first calculating unit calculates the element 1ᵢ at the i-th row and the (i−1)-th column in the lower triangular matrix L, the second calculating unit calculates the element uᵢ at the i-th row and the i-th column in the upper triangular matrix U and the third calculating unit calculates the i-th element yᵢ in the unknown matrix Y of the first linear equation system simultaneously. Then, the first calculating unit calculates an element 1ᵢ₊₁ at an (i+1)-th row and the i-th column in the lower triangular matrix L in the next calculation period.

Reference is made to FIG. 3, which is a timing diagram illustrating for the four calculating units, for representing tasks to be processed by the four calculating units in time domain. In FIG. 3, a vertical axis indicates reference numerals of the four calculating units, and a horizontal axis represents the time. Moreover, the calculating units perform tasks depending on time periods, each of the time periods is considered as the calculation period. As shown in FIG. 3, a time period from a time instant t₂ᵢ to a time instant t₂ᵢ₊₁ is a calculation period, and a time period from the time instant t₂ᵢ₊₁ to a time instant t₂ᵢ₊₂ is another calculation period.

When the calculating module solves the original linear equation system, the first calculating unit 101 first calculates an element 12 in the lower triangular matrix L during a calculation period. During this calculation period, the other three calculating units are on standby. During a next calculation period, the second calculating unit 102 calculates an element u₂ in the upper triangular matrix U, and the third calculating unit 103 calculates a second element y₂ in the unknown matrix Y of the first linear equation system. During this calculation period, the first calculating unit 101 waits for the second calculating unit 102 to calculate the element u₂ in the upper triangular matrix U. During a next calculation period, that is, after the second calculating unit 102 calculates the element u₂ in the upper triangular matrix U, the first calculating unit 101 calculates an element 13 in the lower triangular matrix L, and the second calculating unit 102 and the third calculating unit 103 are on standby.

As shown in FIG. 3, the calculation period following the first calculating unit 101 calculating the element 1ᵢ at the i-th row and the (i−1)-th column in the lower triangular matrix L is from the time instant t₂ᵢ to the time instant t₂ᵢ₊₁. During this calculation period, the second calculating unit 102 calculates the element uᵢ at the i-th row and the i-th column in the upper triangular matrix U, and the third calculating unit 103 calculates the i-th element yᵢ in the unknown matrix of the first linear equation system. The calculation period following the second calculating unit 102 calculating the element uᵢ at the i-th row and the i-th column in the upper triangular matrix U is from the time instant t₂ᵢ₊₁ to a time instant t₂ᵢ₊₂. During this calculation period, the first calculating unit 101 calculates the element 1ᵢ₊₁ at the (i+1)-th row and the i-th column in the lower triangular matrix L. Correspondingly, a calculation period from the time instant t₂ᵢ₊₂ to a time instant t₂ᵢ₊₃ follows the first calculating unit 101 calculating the element 1ᵢ₊₁ in the lower triangular matrix L. During this calculation period, the second calculating unit 102 calculates the element uᵢ₊₁ in the upper triangular matrix U, and the third calculating unit 103 calculates the element yᵢ₊₁ in the unknown matrix Y of the first linear equation system. The similar steps are performed until the third calculating unit 103 calculates a last element yₙ in the unknown matrix Y of the first linear equation system. As shown in FIG. 3, at the time instant t₂ₙ₊₁, the third calculating unit 103 calculates the element yₙ. From the time instant t₂ₙ₊₁, the fourth calculating unit 104 recursively determines elements xₙ, xₙ₋₁, . . . , x₁ in the unknown matrix X of the original linear equation system, and ultimately the differential equation is solved. The calculating module may perform multiple calculations simultaneously, that is, parallel calculations, to improve the calculating speed, thereby improving the calculating speed of the electrochemical model through hardware.

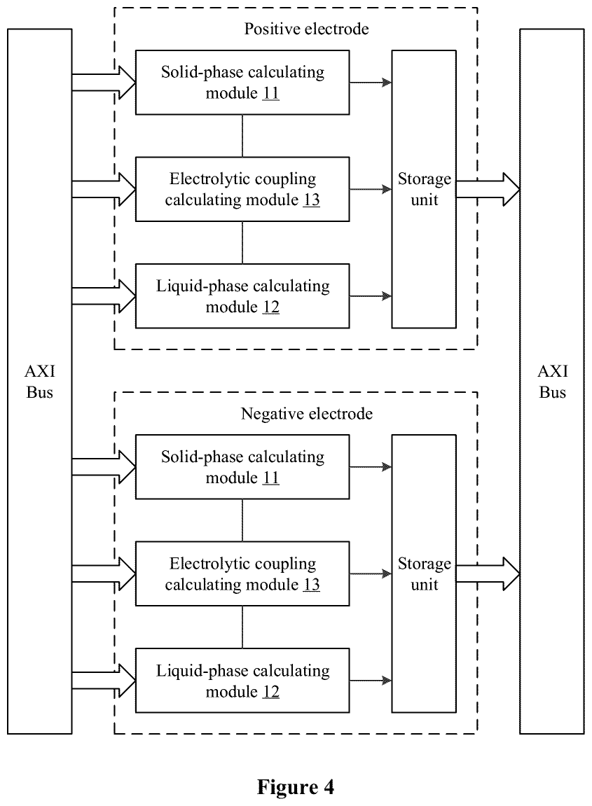

In an embodiment, FIG. 4 is a schematic structural diagram illustrating an FPGA. As shown in FIG. 4, each of the positive electrode and the negative electrode of the electrochemical model is provided with the solid-phase calculating module 11, the liquid-phase calculating module 12, and the electrolytic coupling calculating module 13. The solid-phase calculating module 11 includes a positive solid-phase calculating module 11 for determining a positive solid-phase electrochemical parameter and a negative solid-phase calculating module 11 for determining a negative solid-phase electrochemical parameter. The liquid-phase calculating module 12 includes a positive liquid-phase calculating module 12 for determining a positive liquid-phase electrochemical parameter and a negative liquid-phase calculating module 12 for determining a negative liquid-phase electrochemical parameter. The electrolytic coupling calculating module 13 includes a positive electrolytic coupling calculating module 13 for determining a positive electrolytic coupling electrochemical parameter and a negative electrolytic coupling calculating module 13 for determining a negative electrolytic coupling electrochemical parameter.

Each of the calculating modules at the positive electrode and the negative electrode include the first calculating unit 101, the second calculating unit 102, the third calculating unit 103, and the fourth calculating unit 104. Each of the four calculating units is configured to solve a corresponding differential equation. As shown in FIG. 4, data transmission is implemented through an AXI (Advanced Extensible Interface) bus in the FPGA. For example, as shown in FIG. 4, the calculating modules transmit respective processing results (i.e. the calculated electrochemical parameters) to the storage unit for storage, and thence to other components through the AXI bus.

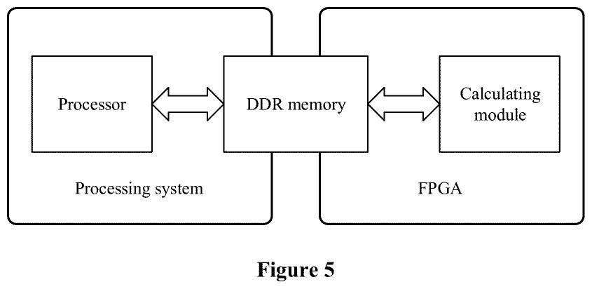

In an embodiment, as shown in FIG. 5, the computing terminal further includes: a processing system. The FPGA is configured to transmit the determined electrochemical parameters to the processing system.

In the embodiment of the present disclosure, the computing terminal is equivalent to a programmable system on chip (SoC), which includes the processing system (PS) and the FPGA. The FPGA is also programmable logic (PL). For example, the computing terminal may be a processing platform of a ZYNQ series. The data transmission is implemented between the processing system and the FPGA through the AXI bus. The processing system may provide an initial value for solving the differential equation to the FPGA through the AXI bus, for the multiple calculating modules of the FPGA to solve the differential equation. Further, the multiple calculating modules of the FPGA transmit the solution results to the processing system through the AXI bus.

Hereinafter, details about operation of the computing terminal are described with an example that the electrochemical model is a P2D model.

A processor in the processing system transmits a parameter for a P2D algorithm to the calculating module of the FPGA through the AXI bus for performing the algorithm configuration. Parameters of a battery are adapted to the cell and the brand of the battery. Moreover, the calculating module receives the parameters and performs initialization.

Then, a charging/discharging operation is performed and input current information is recorded in real time. The collected input current information is transmitted through the AXI bus to a P2D algorithm IP (intellectual property) core in the FPGA. The FPGA is configured to accelerate the calculation for the P2D algorithm, which can reduce power consumption and accelerate algorithm operation through the parallel operation. Ultimately, the FPGA transmits the identified electrochemical parameters to the processing system through the AXI bus. In addition, after the electrochemical parameters of the electrochemical model are determined, parameters of the battery, such as an effective voltage of the battery, may further be calculated based on the electrochemical model.

In an embodiment, the computing terminal further includes a memory. The memory is a memory on chip. As shown in FIG. 5, the memory may be a DDR (Double Data Rate) memory, thereby transmitting data between the processing system and the FPGA through the AXI bus.

Embodiments of the present disclosure are described above. However, the protection scope of the present disclosure is not limited thereto. Changes and substitutions readily obtained by those skilled in the art within the technical scope disclosed in the present application should fall within the protection scope of the present disclosure. Therefore, the protection scope of the present disclosure should be subject to the protection scope of the claims.

1. A computing terminal for parameter identification, comprising: an FPGA, wherein the FPGA comprises
a solid-phase calculating module, configured to solve a solid-phase differential equation to determine a solid-phase electrochemical parameter of an electrochemical model;
a liquid-phase calculating module, configured to solve a liquid-phase differential equation to determine a liquid-phase electrochemical parameter of the electrochemical model; and
an electrolytic coupling calculating module, configured to solve an electrolytic coupling differential equation to determine an electrolytic coupling electrochemical parameter of the electrochemical model, wherein at least some of the solid-phase calculating module, the liquid-phase calculating module, and the electrolytic coupling calculating module are configured to operate in parallel.

2. The computing terminal according to claim 1, wherein a calculating module comprises a plurality of calculating units, and the calculating module is the solid-phase calculating module, the liquid-phase calculating module, or the electrolytic coupling calculating module, wherein
some of the plurality of calculating units are configured to recursively optimize a coefficient matrix of an original linear equation system, and the original linear equation system is obtained by discretizing a to-be-solved differential equation; and
the other calculating units are configured to recursively solve the linear equation system with the optimized coefficient matrix.

3. The computing terminal according to claim 2, wherein the calculating module comprises:
a first calculating unit, configured to recursively calculate elements in a lower triangular matrix determined by performing LU decomposition on the coefficient matrix of the original linear equation system;
a second calculating unit, configured to recursively calculate elements in an upper triangular matrix determined by performing the LU decomposition on the coefficient matrix of the original linear equation system;
a third calculating unit, configured to recursively solve a first linear equation system to determine an unknown matrix of the first linear equation system, wherein a coefficient matrix of the first linear equation system is the lower triangular matrix, and a constant matrix of the first linear equation system is a constant matrix of the original linear equation system; and
a fourth calculating unit, configured to recursively solve a second linear equation system to determine an unknown matrix of the second linear equation system, wherein a coefficient matrix of the second linear equation system is the upper triangular matrix, and a constant matrix of the second linear equation system is the unknown matrix of the first linear equation system.

4. The computing terminal according to claim 3, wherein the constant matrix of the original linear equation system is a tridiagonal matrix.

5. The computing terminal according to claim 4, wherein
the first calculating unit is configured to calculate an element 1ᵢ at an i-th row and an (i−1)-th column in the lower triangular matrix after an element uᵢ₋₁ at an (i−1)-th row and an (i−1)-th column in the upper triangular matrix is determined by the second calculating unit;
the second calculating unit is configured to calculate an element uᵢ at an i-th row and an i-th column in the upper triangular matrix after the element 1ᵢ at the i-th row and the (i−1)-th column in the lower triangular matrix is determined by the first calculating unit;
the third calculating unit is configured to calculate an i-th element yᵢ in the unknown matrix of the first linear equation system after the element 1ᵢ at the i-th row and the (i−1)-th column in the lower triangular matrix is determined by the first calculating unit; and
the fourth calculating unit is configured to calculate the unknown matrix of the second linear equation system after the unknown matrix of the first linear equation system is determined by the third calculating unit.

6. The computing terminal according to claim 5, wherein
the second calculating unit is configured to calculate the element uᵢ at the i-th row and the i-th column in the upper triangular matrix and the third calculating unit is configured to calculate the i-th element yᵢ in the unknown matrix of the first linear equation system in a calculation period after the element 1ᵢ at the i-th row and the (i−1)-th column in the lower triangular matrix is determined by the first calculating unit; and
the first calculating unit is configured to calculate an element 1ᵢ₋₁ at an (i+1)-th row and the i-th column in the lower triangular matrix in a calculation period after the element uᵢ at the i-th row and the i-th column in the upper triangular matrix is determined by the second calculating unit.

7. The computing terminal according to claim 5, wherein,
the fourth calculating unit is configured to calculate a k-th element xₖ in the unknown matrix of the second linear equation system based on recursion in reverse order, wherein k=n−1, n−2, . . . , 1, and n represents the number of nodes for discretizing the differential equation.

8. The computing terminal according to claim 5, wherein,
the element 1ᵢ at the i-th row and the (i−1)-th column in the lower triangular matrix is calculated from;
the element uᵢ at the i-th row and the i-th column in the upper triangular matrix is calculated from;
the i-th element yᵢ in the unknown matrix of the first linear equation system is calculated from; and
a k-th element xₖ in the unknown matrix of the second linear equation system is calculated from;
wherein i=2, 3, . . . , n, k=n−1, n−2, . . . , 1, n represents the number of nodes for discretizing the differential equation; aᵢ represents an element at an i-th row and an (i−1)-th column in the tridiagonal matrix, b; represents an element at the i-th row and an i-th column in the tridiagonal matrix, cᵢ represents an element at the i-th row and an (i+1)-th column in the tridiagonal matrix, and dᵢ represents an i-th element in the constant matrix of the original linear equation system; b₁ represents an element at a first row and a first column in the tridiagonal matrix, c₁ represents an element at the first row and a second column in the tridiagonal matrix, d₁ represents a first element in the constant matrix of the original linear equation system, u₁ represents an element at a first row and a first column in the upper triangular matrix, and y₁ represents a first element in the unknown matrix of the first linear equation system; and xₙ represents an n-th element in the unknown matrix of the second linear equation system.

9. The computing terminal according to claim 1, wherein,
the solid-phase calculating module comprises: a positive solid-phase calculating module configured to determine a positive solid-phase electrochemical parameter; and a negative solid-phase calculating module configured to determine a negative solid-phase electrochemical parameter;
the liquid-phase calculating module comprises: a positive liquid-phase calculating module configured to determine a positive liquid-phase electrochemical parameter; and a negative liquid-phase calculating module configured to determine a negative liquid-phase electrochemical parameter; and
the electrolytic coupling calculating module comprises; a positive electrolytic coupling calculating module configured to determine a positive electrolytic coupling electrochemical parameter; and a negative electrolytic coupling calculating module configured to determine a negative electrolytic coupling electrochemical parameter.

10. The computing terminal according to claim 1, further comprising: a processing system, wherein
the FPGA is configured to transmit the determined electrochemical parameters to the processing system.
